(19) United States
(12) Patent Application Publication
(10) Pub. No.: US 2025/0221043 A1
(43) Pub. Date: Jul. 3, 2025

(54) DISPLAY PANEL AND DISPLAY DEVICE

(71) Applicants: Wuhan Tianma Micro-Electronics Co., Ltd., Wuhan (CN); Wuhan Tianma Micro-Electronics Co., Ltd. Shanghai Branch, Shanghai (CN)

(72) Inventors: Huiping CHAI, Wuhan (CN); Gaojun HUANG, Wuhan (CN)

(21) Appl. No.: 18/782,682

(22) Filed: Jul. 24, 2024

(30) Foreign Application Priority Data
Dec. 28, 2023 (CN) 202311866833.1

(51) Int. Cl. H01L 27/12

(52) U.S. Cl. CPC H10D 86/60; H10D 86/441

(57) ABSTRACT

A display panel and a display device are provided. The display panel includes a pixel driving circuit including a plurality of transistors, a base substrate, and a light-shielding layer disposed on a side of the base substrate. The light-shielding layer includes a light-shielding block and a first signal line, and in a direction perpendicular to a plane of the base substrate, an active area of at least one transistor of the plurality of transistors overlaps with the light-shielding block. The display panel also includes a reference power signal line. The first signal line and the reference power signal line are electrically connected, extension directions of the first signal line and the reference power signal line are consistent, and in the direction perpendicular to the plane of the base substrate, the first signal line overlaps with the reference power signal line.

### CROSS-REFERENCE TO RELATED APPLICATION

This application claims priority of Chinese Patent Application No. 202311866833.1, filed on Dec. 28, 2023, the entire content of which is hereby incorporated by reference.

### FIELD OF THE DISCLOSURE

The present disclosure generally relates to the field of display technology and, more particularly, relates to a display panel and a display device.

### BACKGROUND

A pixel driving circuit of a display panel may include a plurality of transistors. In a process of controlling a display panel to display an image, it is necessary to control whether, and for how long, light-emitting elements in the display panel to emit light, through on-off control of transistors in a pixel driving circuit.

In some application scenarios, the display panel may be irradiated by external light. When the transistors in the display panel are exposed to light, electrical characteristics of the transistors, such as leakage current, may change. The on-off control accuracy of the transistors may be decreased, and the display effect of the display panel may be affected. Simultaneously, since the voltage drop on some signal lines in the display panel, such as the reference power signal line, may vary greatly at different positions of the display panel, corresponding signals may vary greatly at different positions of the display panel. As a result, display uniformity of the display panel may be affected.

### SUMMARY

One aspect of the present disclosure includes a display panel. The display panel includes a pixel driving circuit including a plurality of transistors, a base substrate, and a light-shielding layer disposed on a side of the base substrate. The light-shielding layer includes a light-shielding block and a first signal line, and in a direction perpendicular to a plane of the base substrate, an active area of at least one transistor of the plurality of transistors overlaps with the light-shielding block. The display panel also includes a reference power signal line. The first signal line and the reference power signal line are electrically connected, extension directions of the first signal line and the reference power signal line are consistent, and in the direction perpendicular to the plane of the base substrate, the first signal line overlaps with the reference power signal line.

Another aspect of the present disclosure includes display device. The display device includes a display panel. The display panel includes a pixel driving circuit including a plurality of transistors, a base substrate, and a light-shielding layer disposed on a side of the base substrate. The light-shielding layer includes a light-shielding block and a first signal line, and in a direction perpendicular to a plane of the base substrate, an active area of at least one transistor of the plurality of transistors overlaps with the light-shielding block. The display panel also includes a reference power signal line. The first signal line and the reference power signal line are electrically connected, extension directions of the first signal line and the reference power signal line are consistent, and in the direction perpendicular to the plane of the base substrate, the first signal line overlaps with the reference power signal line.

Other aspects of the present disclosure may be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a structural top view of a display panel consistent with the disclosed embodiments of the present disclosure;

FIG. 2 illustrates a schematic film-structure diagram of a display panel consistent with the disclosed embodiments of the present disclosure;

FIG. 3 illustrates another schematic film-structure diagram of a display panel consistent with the disclosed embodiments of the present disclosure;

FIG. 4 illustrates another schematic film-structure diagram of a display panel consistent with the disclosed embodiments of the present disclosure;

FIG. 5 illustrates another schematic film-structure diagram of a display panel consistent with the disclosed embodiments of the present disclosure;

FIG. 6 illustrates a schematic structural diagram of a pixel driving circuit consistent with the disclosed embodiments of the present disclosure;

FIG. 7 illustrates a schematic diagram of timing control consistent with the disclosed embodiments of the present disclosure;

FIG. 8 illustrates another schematic structural diagram of a pixel driving circuit consistent with the disclosed embodiments of the present disclosure;

FIG. 9 illustrates a structural top view of another display panel consistent with the disclosed embodiments of the present disclosure;

FIG. 10 illustrates another schematic film-structure diagram of a display panel consistent with the disclosed embodiments of the present disclosure;

FIG. 11 illustrates a structural top view of another display panel consistent with the disclosed embodiments of the present disclosure;

FIG. 12 illustrates a structural top view of another display panel consistent with the disclosed embodiments of the present disclosure;

FIG. 13 illustrates a top view of a film layer stack structure of a display panel consistent with the disclosed embodiments of the present disclosure;

FIG. 14 illustrates a top view of another film layer stack structure of a display panel consistent with the disclosed embodiments of the present disclosure;

FIG. 15 illustrates a top view of another film layer stack structure of a display panel consistent with the disclosed embodiments of the present disclosure;

FIG. 16 illustrates another schematic film-structure diagram of a display panel consistent with the disclosed embodiments of the present disclosure;

FIG. 17 illustrates another schematic film-structure diagram of a display panel consistent with the disclosed embodiments of the present disclosure;

FIG. 18 illustrates a structural top view of another display panel consistent with the disclosed embodiments of the present disclosure;

FIG. 19 illustrates a top view of another film layer stack structure of a display panel consistent with the disclosed embodiments of the present disclosure;

FIG. 20 illustrates a top view of another film layer stack structure of a display panel consistent with the disclosed embodiments of the present disclosure; and

FIG. 21 illustrates a schematic structural diagram of a display device consistent with the disclosed embodiments of the present disclosure.

### DETAILED DESCRIPTION

To make the objectives, technical solutions and advantages of the present disclosure clearer and more explicit, the present disclosure is described in further detail with accompanying drawings and embodiments. It should be understood that the specific exemplary embodiments described herein are only for explaining the present disclosure and are not intended to limit the present disclosure.

Technologies, methods, and equipment known to those of ordinary skill in relevant fields may not be discussed in detail, but where appropriate, these technologies, methods, and equipment should be regarded as part of the specification.

Reference will now be made in detail to embodiments of the present disclosure, which are illustrated in the accompanying drawings. Similar labels and letters designate similar items in the drawings. Once an item is defined in one drawing, the item may not be defined and discussed in subsequent drawings.

In a display panel, external light may directly illuminate an active area of a transistor. Research indicates that electrical characteristics of a transistor may change under the action of light. As such, the control signal may not accurately control on/off states of the transistor, and the display effect of the display panel may be affected. In addition, since the voltage drop on some signal lines in the display panel, such as the reference power signal line, may vary greatly at different positions of a display panel, corresponding signals vary greatly at different positions of the display panel. As a result, display uniformity of the display panel may be affected.

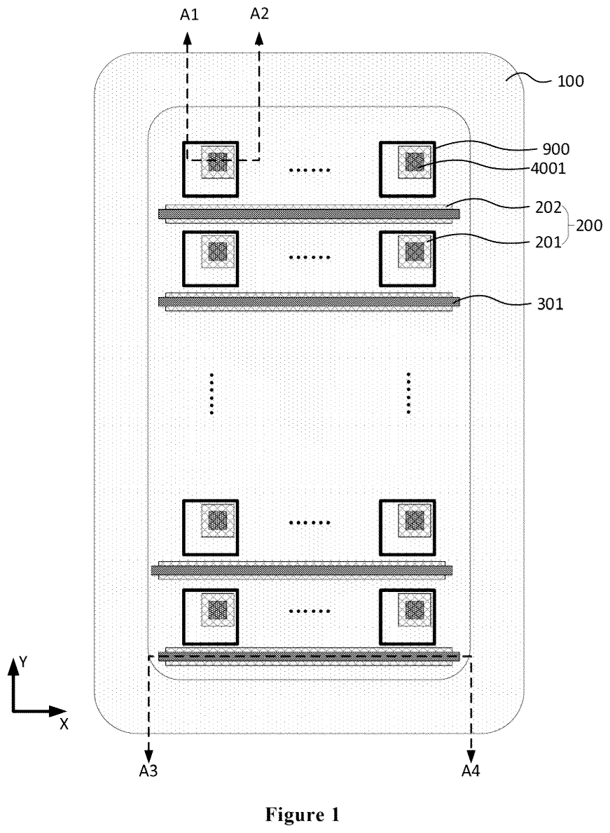

To solve the above technical problems, the present disclosure provides a display panel and a display device. FIG. 1 illustrates a structural top view of a display panel consistent with the disclosed embodiments of the present disclosure. Referring to FIG. 1, the display panel includes: a pixel driving circuit 900 including a plurality of transistors 400; a base substrate 100; and a light-shielding layer 200 disposed on a side of the base substrate 100. The light-shielding layer 200 includes a light-shielding block 201 and a first signal line 202. The transistor 400 includes an active area 4001. In a direction perpendicular to a plane of the base substrate 100, the active area 4001 of at least one transistor overlaps with the light-shielding block 201. The display panel also includes a reference power signal line 301. The first signal line 202 and the reference power signal line 301 are electrically connected (the electrical connection relationship is not shown in FIG. 1). Extension directions of the first signal line 202 and the reference power signal line 301 are consistent. In a direction perpendicular to the plane of the base substrate 100, the first signal line 202 overlaps with the reference power signal line 301.

The pixel driving circuit 900 represents a functional circuit for controlling light-emitting elements to emit light such that the display panel may display an image. The pixel driving circuit 900 includes a plurality of transistors. By inputting a specific electrical signal to each transistor, the on/off state of the transistor may be controlled, and the transistor may be controlled to output a specific electrical signal to control whether the light-emitting element emits light and/or to control the lighting duration of the light-emitting element. The light-shielding layer 200 represents a functional film layer for blocking light, and the light-shielding layer 200 may be made of a metal conductive material. In one embodiment, the light-shielding block 201 and the first signal line 202 may each be prepared by patterning the light-shielding layer 200. The light-shielding block 201 is configured to shield the active area 4001 in the transistor. The first signal line 202 is configured to electrically connect with the reference power signal line 301 and transmit the reference power signal on the reference power signal line 301.

FIG. 1 schematically illustrates the base substrate 100, the light-shielding layer 200 and a semiconductor layer 300 in the display panel. As exemplarily shown in FIG. 1, the active area 4001 of the transistor and the reference power signal line 301 may be prepared from the semiconductor layer 300. In the accompanying drawings of the present disclosure, a plane formed by an X direction and a Y direction is parallel to the plane where the display panel is located, and a Z direction is perpendicular to the plane where the display panel is located.

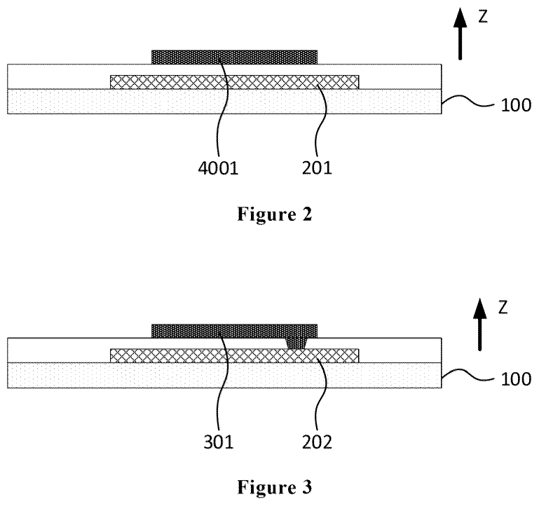

FIG. 2 illustrates a schematic film-structure diagram of a display panel consistent with the disclosed embodiments of the present disclosure. FIG. 2 is a schematic cross-sectional view along the A1A2 direction of the display panel illustrated in FIG. 1. It may be seen from a structure corresponding to FIGS. 1 and 2 that the light-shielding block 201 may overlap with the active area 4001 of the transistor in a direction perpendicular to the plane of the display panel. The active area 4001 of the transistor may be located within a projection of the light-shielding block 201 in the direction perpendicular to the plane of the display panel. As such, the light-shielding block 201 may block light and prevent the light from irradiating the active area 4001 of the transistor. As such, even in a lighting environment, the electrical characteristics of the transistor may not be affected much by the lighting. Accordingly, the control signal may accurately control the transistor, and the display panel may operate accurately based on the control signal. As a result, the display effect of the display panel under a lighting environment may be improved.

FIG. 3 illustrates another schematic film-structure diagram of a display panel consistent with the disclosed embodiments of the present disclosure. FIG. 3 is a schematic cross-sectional view along the A3A4 direction of the display panel shown in FIG. 1. It may be seen from a structure corresponding to FIGS. 1 and 3 that the first signal line 202 and the reference power signal line 301 may extend in a same direction, and may be electrically connected. As such, the first signal line 202 may be used to reduce the resistance of the reference power signal line 301. Accordingly, voltage drop difference of the reference power signal in the reference power signal line 301 at different positions of the display panel may be reduced, and consistency of the reference power signal at different positions of the display panel may be improved. As such, display uniformity of the display panel may be improved. In addition, the first signal line 202 occupies a small additional area in the plane of the base substrate 100, space may be reserved for laying out other wirings and other structures, and the flexibility of laying out other wirings and other structures may be improved.

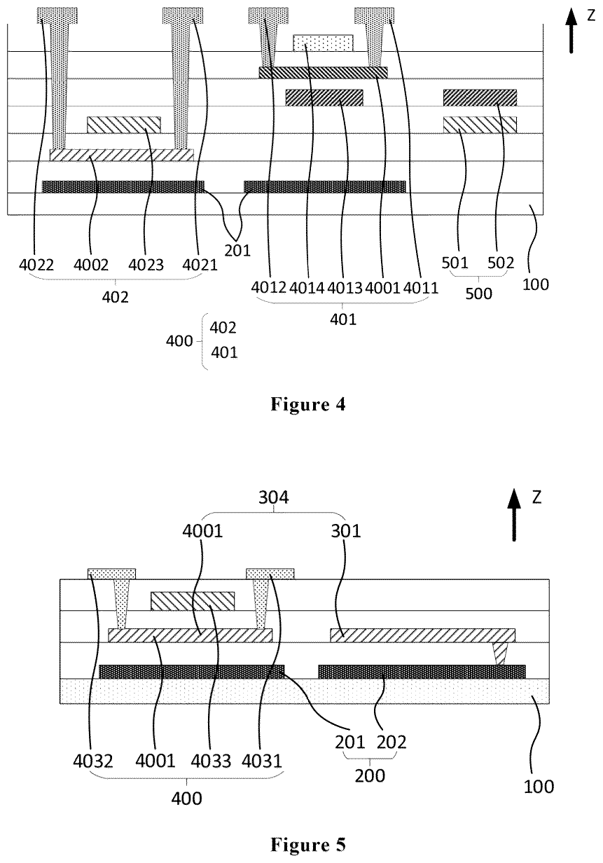

FIG. 4 illustrates another schematic film-structure diagram of a display panel consistent with the disclosed embodiments of the present disclosure. In some embodiments, the transistors 400 includes a first transistor 401 and a second transistor 402. The pixel driving circuit 900 also includes: a first capacitor 500, where the first transistor 401 and the second transistor 402 each are electrically connected to the first capacitor 500; a first semiconductor layer located on a side of the light-shielding layer 200 facing away from the base substrate 100, where the first semiconductor layer includes the active area 4001 of the first transistor 401; and a second semiconductor layer located between the first semiconductor layer and the light-shielding layer 200. The second semiconductor layer includes an active area 4002 of the second transistor 402.

FIG. 4 schematically illustrates the first transistor 401 and the second transistor 402. It should be noted that FIG. 4 only illustrates part of the film layer structure in the display panel, and does not illustrate electrical connection relationships between the first transistor 401, the second transistor 402 and the first capacitor 500. As shown in FIG. 4, 501 represents a first plate of the first capacitor 500, and 502 represents a second plate of the first capacitor 500.

The first transistor 401 may include source and drain metal layers, represented by 4011 and 4012 respectively in FIG. 4. One of 4011 and 4012 is the source and the other is the drain. The first semiconductor layer is used to prepare the active area 4001 of the first transistor 401. The first transistor 401 also includes a first gate 4013 and a second gate 4014, forming a top gate and a bottom gate respectively, to improve the electrical performance of the second transistor 402, which will not be elaborated here. The second transistor 402 may include source and drain metal layers, represented by 4021 and 4022 respectively in FIG. 4. One of 4021 and 4022 is the source and the other is the drain. The second semiconductor layer is used to prepare the active area 4001 of the second transistor 402. The second transistor 402 also includes a third gate 4023. For sake of description simplicity, some of the insulating layers in FIG. 4 are not be described or illustrated in detail.

In one embodiment, the second semiconductor layer being located between the first semiconductor layer and the light-shielding layer 200 means that the second semiconductor layer is located between the first semiconductor layer and the light-shielding layer 200 at a spatial level perpendicular to the plane direction of the display panel. The present disclosure does not strictly limit an overlapping relationship between the second semiconductor layer and the first semiconductor layer in a direction perpendicular to the plane of the display panel. Along a direction parallel to the plane of the display panel, there are no specific restrictions on positions of the second semiconductor layer, the first semiconductor layer and the light-shielding layer 200.

In some embodiments, the second semiconductor layer and the first semiconductor layer are made of different materials.

With continuous reference to FIG. 4, the second semiconductor layer may be made of a material including low temperature polysilicon (LTPS), and the first semiconductor layer may be made of a material including indium gallium zinc oxide (IGZO). Compared with low-temperature polysilicon, indium gallium zinc oxide may have characteristics of high mobility, high on-state current, low off-state current, and rapid switching. In one embodiment, the display panel includes the first transistor 401 made of the first semiconductor layer and the second transistor 402 made of a second semiconductor layer are simultaneously. Accordingly, the display panel may not only have the advantages of high resolution, high response speed, high brightness, high aperture ratio, etc. of an LTPS display panel, but also have the advantage of small leakage current of IGZO.

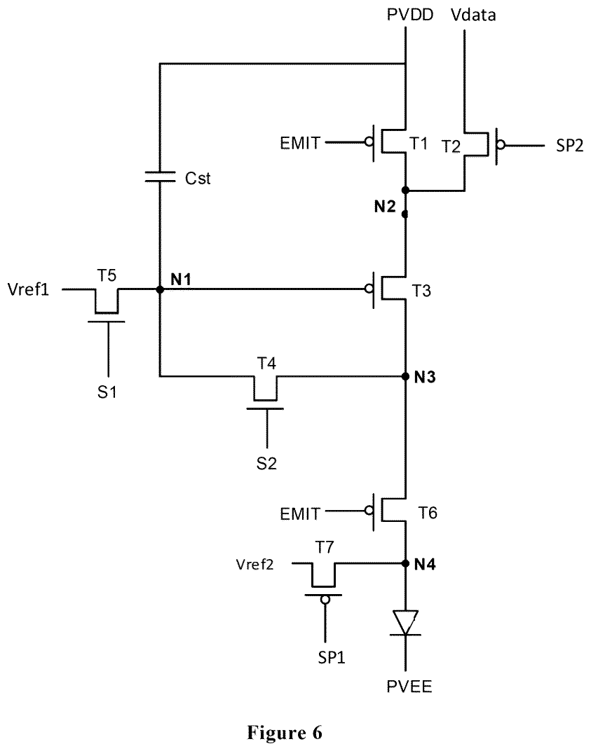

FIG. 5 illustrates another schematic film-structure diagram of a display panel consistent with the disclosed embodiments of the present disclosure. In some embodiments, the display panel also includes a third semiconductor layer 304 including an active area 4001 of at least one transistor 400. The reference power signal line 301 and the third semiconductor layer 304 may be disposed on a same layer.

In a display panel, the reference power signal line 301 is generally made of a metal film layer. In a same metal film layer, the greater the quantity of wiring, the greater the wiring complexity and difficulty. In FIG. 5, the transistor 400 may include a source and a drain, represented by 4031 and 4032 respectively. One of 4031 and 4032 represents the source, and the other represents the drain. The gate is represented by 4033. The transistor 400 also includes an active area 4001.

In one embodiment, the reference power signal line 301 and the third semiconductor layer 304 may be disposed in a same layer. The reference power signal line 301 is made of the third semiconductor layer 304 and transmits the reference power signal. Specifically, the material of the third semiconductor layer 304 is a semiconductor. In one embodiment, while preparing the active area 4001 of the transistor 400 based on the third semiconductor layer 304, the wiring for transmitting the reference power signal may be prepared simultaneously. The wiring for transmitting the reference power signal may be conductorized to form the reference power signal line 301. After conductorizing the wiring made from the third semiconductor layer 304 to form the reference power signal line 301, the reference power signal line 301 may transmit the reference power signal.

The third semiconductor layer 304 and the second semiconductor layer may be a same layer. The material of the third semiconductor layer 304 may be low-temperature polysilicon. As such, in one embodiment, the third semiconductor layer 304 may be multiplexed for transmitting the reference power signal, and other metal film layers originally used to fabricate the reference power signal line 301 may not need to be used to fabricate the reference power signal line 301. Accordingly, wiring space of other metal film layers may be saved.

FIG. 6 illustrates a schematic structural diagram of a pixel driving circuit consistent with the disclosed embodiments of the present disclosure. In some embodiments, the transistor 400 includes: a power writing transistor T1, a data writing transistor T2, a driving transistor T3, a first reset transistor T5, a threshold compensation transistor T4, a light-emitting control transistor T6, and a second reset transistor T7. The pixel driving circuit 900 also includes a second capacitor Cst. The threshold compensation transistor T4 is electrically connected between the gate and the first electrode of the driving transistor T3. The first electrode of the power writing transistor T1 and the first electrode of the data writing transistor T2 each are electrically connected to the second electrode of the driving transistor T3. The second electrode of the power writing transistor T1 is electrically connected to the second plate of the second capacitor Cst. The gate of the driving transistor T3 and the first electrode of the first reset transistor T5 each are electrically connected to the first plate of the second capacitor Cst. At least one of the second electrode of the first reset transistor T5 and the second electrode of the second reset transistor T7 is electrically connected to the reference power signal line 301. The light-emitting control transistor T6 is connected between the driving transistor T3 and the light-emitting element driven by the pixel driving circuit 900. The first electrode of the second reset transistor T7 is electrically connected to the light-emitting control transistor T6 and the light-emitting element.

FIG. 6 is a 7T1C pixel driving circuit provided by the present disclosure, where “T” represents a transistor, “7T” represents a total of 7 transistors in the pixel driving circuit 900, “C” represents a capacitor, and “1C” represents a total of 1 capacitor in the pixel driving circuit 900. In the pixel driving circuit 900, the power writing transistor T1, the data writing transistor T2, the driving transistor T3, the light-emitting control transistor T6, and the second reset transistor T7 each are P-type transistors. The first reset transistor T5 and the threshold compensation transistor T4 each are N-type transistors. The diode in FIG. 6 represents a light-emitting element. Correspondingly, the signal lines may include a scan signal line, the reference power signal line 301, the power signal line, and a data line Vdata. The scan signal line includes a first scan signal line SCAN1, a second scan signal line SCAN2, a light-emitting control scan signal line EMIT, a third scanning signal line SP2 and a bias control signal line SP1. The reference power signal line 301 includes at least one of a first reference power signal line Vref1 and a second reference power signal line Vref2. The power signal line includes a first power signal line PVDD and a second power signal line PVEE.

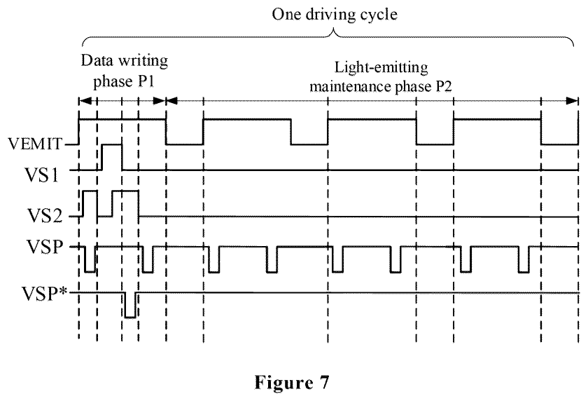

FIG. 7 illustrates a schematic diagram of timing control consistent with the disclosed embodiments of the present disclosure. FIG. 7 is a timing control diagram of the pixel driving circuit 900 corresponding to FIG. 6. The operation process of the pixel driving circuit 900 may be understood with reference to FIGS. 6 and 7. The first scanning signal VS1 of the first scanning signal line SCAN1 controls the on/off state of the first reset transistor T5 of the pixel driving circuit 900, and resets the gate potential of the driving transistor T3 when the first reset transistor T5 is turned on. That is, the first power reference signal of the first reference power signal line Vref1 is transmitted to the first reset transistor T5, and the connection node (first node N1) of the driving transistor T3, the first reset transistor T5, the compensation transistor T4 and the storage capacitor Cst is reset. The third scanning signal VSP* of the third scanning signal line SP2 controls the on/off state of the data writing transistor T2 of the pixel driving circuit 900. When the data writing transistor T2 is turned on, the data signal on the data signal line Vdata is written to the gate of the driving transistor T3. The second scanning signal VS2 of the second scanning signal line SCAN2 controls the on/off state of the compensation transistor T4. When the compensation transistor T4 is turned on, the threshold voltage of the driving transistor T3 is compensated. Simultaneously, the bias control signal line SP1 controls the on/off state of the second reset transistor T7. When the second reset transistor T7 is turned on, the anode of the light-emitting element connected to the pixel driving circuit 900 is reset. That is, the first reference power signal of the first reference power signal line Vref1 is transmitted to the anode of the light-emitting element. The light-emitting control scan signal VEMIT of the light-emitting control scan signal line EMIT controls the on/off state of the power writing transistor T1 and the light-emitting control transistor T6. When the control power writing transistor T1 and the second light-emitting control transistor T6 are turned on, the first power signal transmitted by the first power line PVDD is transmitted to the light-emitting element, thus realizing the display and light emission of the light-emitting element.

For at least part of the transistors 400 in FIG. 6, the active area 4001 may be blocked by the light-shielding layer 200, preventing light from affecting the electrical characteristics of the transistors 400. Accordingly, the display effect of the display panel under light irradiating environment may be improved.

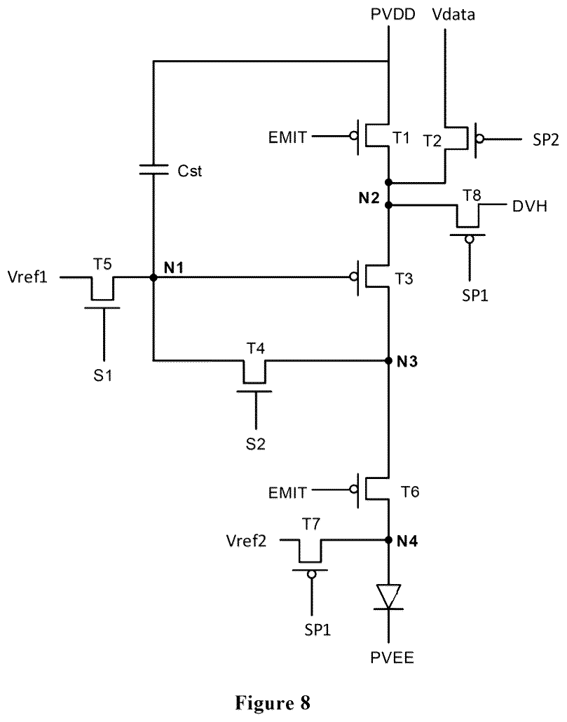

FIG. 8 illustrates another schematic structural diagram of a pixel driving circuit consistent with the disclosed embodiments of the present disclosure. In some embodiments, the transistors 400 also include a bias transistor T8. The bias transistor T8 is electrically connected to the second electrode of the driving transistor T3.

FIG. 8 shows an 8T1C pixel driving circuit 900 obtained by improvement based on FIG. 6. The operation processes of other transistors except the bias transistor T8 may be understood with reference to FIG. 6 and FIG. 7, and will not be elaborated here. Referring to FIGS. 8 and 7, the bias control signal VSP of the bias control signal line SP1 controls the on/off state of the bias transistor T8. When the bias transistor T8 is turned on, bias adjustment may be performed on the driving transistor T3. That is, the bias signal of the bias signal line DVH may be transmitted to the bias transistor T8, and the bias adjustment may be performed on the connection node (second node N2) of the driving transistor T3, the power writing transistor T1, and the data writing transistor T2. Accordingly, the operation stability of the drive transistor T3 may be improved.

The bias control signal VSP may include an enable level and a non-enable level. The enable level may turn on the bias transistor T8, and the non-enable level may turn off the bias transistor T8. When the bias control signal line SP1 controls the bias transistor T8 to turn on, the bias transistor T8 may transmit the bias voltage transmitted on the bias signal line DVH to the second electrode of the driving transistor T3, resetting the second electrode of the driving transistor T3 to improve the brightness of the first frame when the light-emitting element emits light. Accordingly, the brightness of the first frame may not be too low, and display consistency on the display panel may be improved.

In addition, before resetting the gate of the driving transistor T3, by controlling the bias transistor T8 to turn on, the bias voltage provided by the bias signal line DVH may be written into the second electrode of the driving transistor T3. As such, the potential of the second electrode of the driving transistor T3 may be refreshed. Accordingly, the device characteristics of the driving transistor T3 may be set to a certain initial state, and the influence of the data signal written in a previous frame on the device characteristics of the driving transistor T3 may be eliminated.

After writing the data voltage to the driving transistor T3, the voltage of the second electrode of the driving transistor T3 may leak. Especially under low-frequency driving, the leakage may be obvious, leading to a large shift in the potential of the second electrode of the driving transistor T3. In this case, by controlling the bias transistor T8 to turn on, and using the bias transistor T8 to write the bias voltage to the second electrode of the driving transistor T3, the bias state of the driving transistor T3 may stay consistent with the bias state when the data voltage is just written. Accordingly, the stability of the operation state of the driving transistor T3 may be improved, the low-frequency flicker may be eased, and the image display effect of the display panel may thus be improved.

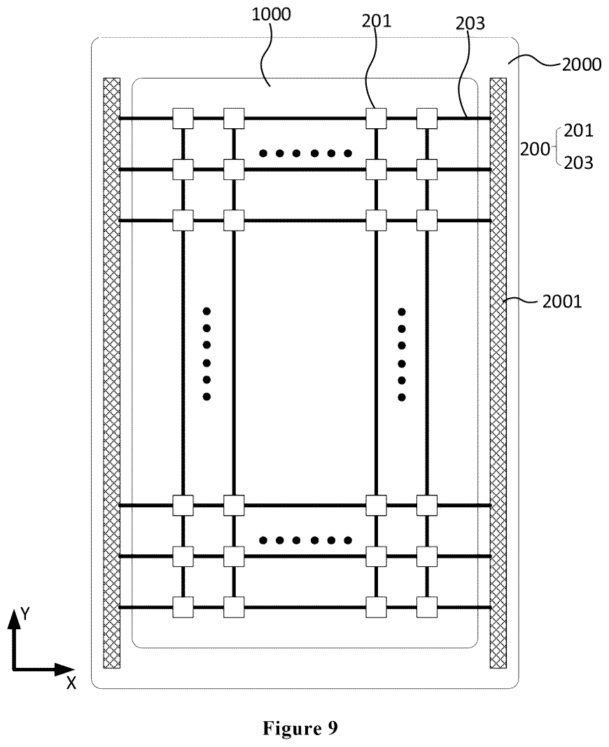

FIG. 9 illustrates a structural top view of another display panel consistent with the disclosed embodiments of the present disclosure. Referring to FIG. 9, in some embodiments, the display panel also includes a display area 1000 and a non-display area 2000 at least partially surrounding the display area 1000. The light-shielding layer 200 also includes an extension portion 203. The extension portion 203 is connected to the light-shielding block 201 in the display area 1000 and extends to the non-display area 2000. The non-display area 2000 also includes a first power main line 2001, and the extension portion 203 is electrically connected to the first power main line 2001.

The first power main line 2001 may be a PVDD signal line. In one embodiment, the extension portion 203 of the light-shielding layer 200 may extend to the non-display area 2000. The extension portion 203 may be electrically connected to the first power main line 2001 of the non-display area 2000, for transmitting the PVDD signal corresponding to the first power main line 2001.

Exemplarily, the light-shielding block 201 may be electrically connected to the corresponding transistor 400 (such as the power writing transistor T1 in FIG. 8) and/or the capacitor (such as the first capacitor 500 in FIG. 4) through a via. As such, the PVDD signal may be transmitted to the corresponding transistor 400 and/or capacitor through the extension portion 203 and the light-shielding block 201.

Accordingly, in one embodiment, the light-shielding layer 200 may be multiplexed to transmit the power signal corresponding to the first power main line 2001. As such, there is no need to dispose other metal layers in the display area 1000 for transmitting the PVDD signal corresponding to the first power main line 2001, and the wiring space in the display area 1000 may be saved.

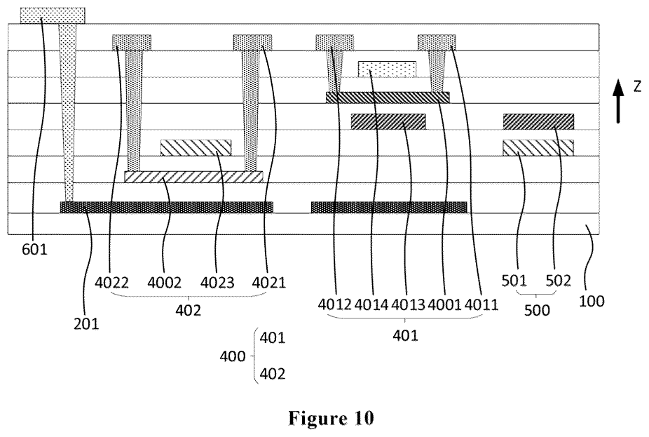

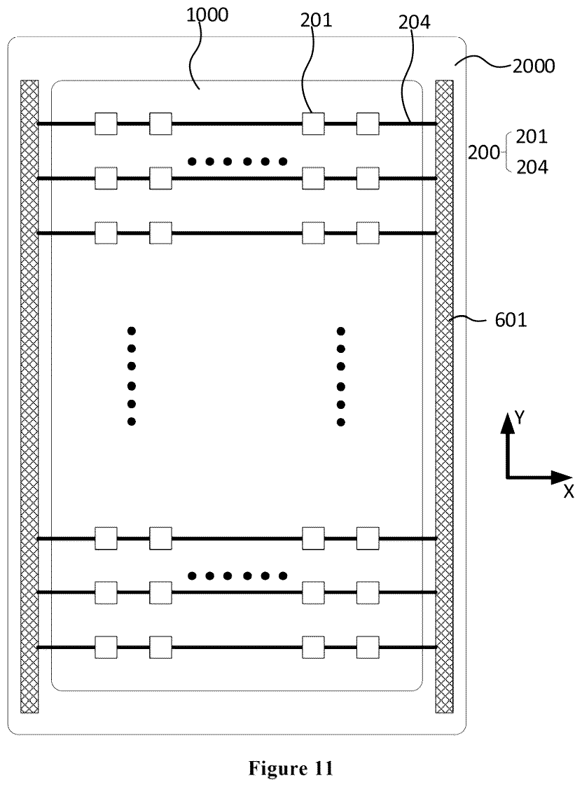

FIG. 10 illustrates another schematic film-structure diagram of a display panel consistent with the disclosed embodiments of the present disclosure. Referring to FIG. 10, in some embodiments, the display panel also includes a first conductive line layer located on a side of the light-shielding layer 200 facing away from the base substrate 100. The first conductive line layer includes a first power signal line 601. In the direction perpendicular to the plane of the base substrate 100, the first power signal line 601 overlaps with the second signal line. The first power signal line 601 and the second signal line are electrically connected through a via in the overlapping area. The second signal line includes the light-shielding blocks 201 that are connected to each other.

Exemplary, the first power signal line 601 may be a PVDD signal line. When the space in the display area is sufficient, the first power signal line 601 and a second signal line 205 may be electrically connected through a via in the display area. The interconnected light-shielding blocks 201 may form a line for transmitting the PVDD signal, reducing the resistance of the first power signal line 601. The voltage drop of the first power signal corresponding to the first power signal line 601 received at different positions of the display panel may be reduced, and the uniformity of the display panel may be improved.

FIG. 11 illustrates a structural top view of another display panel consistent with the disclosed embodiments of the present disclosure. Referring to FIG. 11, in some embodiments, the display panel also includes a first power signal line 601. The first power signal line 601 extends at least along the second direction. The light-shielding layer 200 also includes a connecting portion 204. At least the light-shielding blocks 201 arranged along the first direction are connected to each other through the connecting portion 204 and are connected to the first power signal line 601. The first direction intersects with the second direction.

In FIG. 11, the Y direction represents the second direction, the X direction represents the X direction, 1000 represents the display area, and 2000 represents the non-display area. The light-shielding blocks 201 may be arranged along the first direction in the display panel. Adjacent light-shielding blocks 201 are connected to each other through the connecting portion 204, and are connected to the first power signal line 601. Accordingly, the light-shielding block 201 may be connected based on the connection portion 204 to form a line for the power signal corresponding to the first power signal line 601. A grid-like circuit with the first direction intersecting with the second direction may be formed to reduce the resistance of the first power signal line 601. As such, the voltage drop of the first power signal corresponding to the first power signal line 601 received at different locations in the display panel may be reduced, and the uniformity of the display panel may be improved.

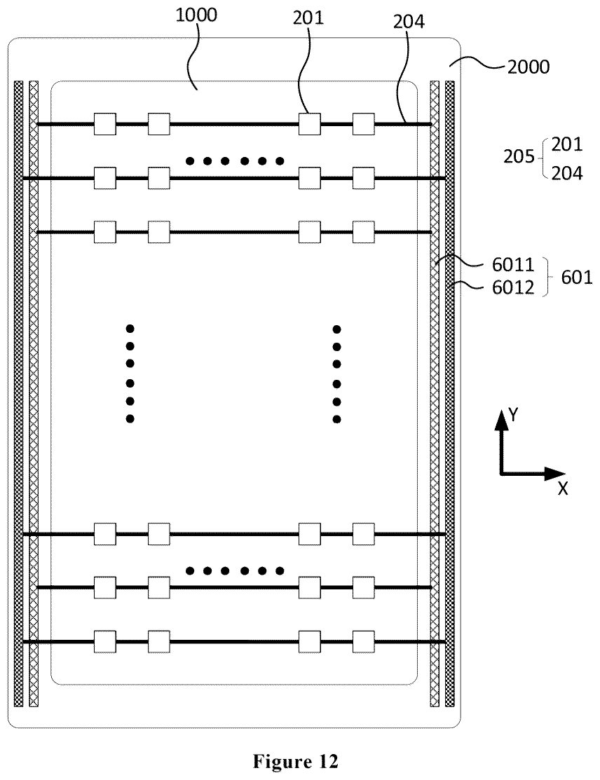

FIG. 12 illustrates a structural top view of another display panel consistent with the disclosed embodiments of the present disclosure. Referring to FIG. 12, in some embodiments, the first power signal line 601 includes a first sub-power signal line 6011 and a second sub-power signal line 6012. At least the light-shielding blocks 201 arranged along the first direction are connected to each other through the connecting portion 204 to form at least two second signal lines 205 extending along the first direction. The first direction intersects with the second direction. At least one second signal line 205 is electrically connected to the first sub-power signal line 6011, and at least another second signal line 205 is electrically connected to the second sub-power signal line 6012.

The display panel may include a PVDD signal line for transmitting PVDD signals and a PVEE signal line for transmitting PVEE signals. In one embodiment, the first sub-power signal line 6011 may be a PVDD signal line, and the second sub-power signal line 6012 may be a PVEE signal line. The light-shielding blocks 201 may be connected to each other through the connecting portion 204 to form a second signal line 205 capable of transmitting signals. The PVDD signal line and the PVEE signal line may extend along the second direction. In one embodiment, part of the second signal lines 205 may be electrically connected to the first sub-power signal line 6011 to transmit the PVDD signal, and another part of the second signal lines 205 may be electrically connected to the second sub-power signal line 6012 to transmit the PVEE signal. Accordingly, in one embodiment, the light-shielding layer 200 may be multiplexed to transmit PVDD signals and PVEE signals, reducing the resistance of the first power signal line 601. The voltage drop of the first power signal corresponding to the first power signal line 601 received at different locations in the display panel may be reduced, and the uniformity of the display panel may be improved.

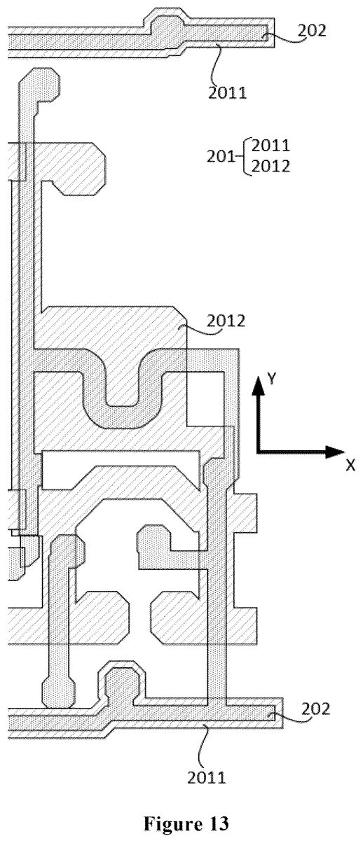

FIG. 13 illustrates a top view of a film layer stack structure of a display panel consistent with the disclosed embodiments of the present disclosure. Referring to FIG. 13, in some embodiments, the first signal line 202 extends along the first direction. Along the second direction, the light-shielding blocks 201 that overlap with a same pixel driving circuit in a direction perpendicular to the plane of the base substrate 100 may be divided into a first group of light-shielding blocks 2011 and a second group of light-shielding blocks 2012. Along the first direction, at least part of the first group of light-shielding blocks 2011 in the display panel are connected to each other and connected to one of the first sub-power signal line and the second sub-power signal line. Along the first direction, at least part of the second group of light-shielding blocks 2012 in the display panel are connected to each other and connected to the other one of the first sub-power signal line and the second sub-power signal line.

In FIG. 13, the first direction is the X direction, and the second direction is the Y direction. Referring to FIG. 13, in the top view of the film layer stack structure of the display panel, film layers with a same filling pattern represent a same film layer, and film layers filled with different patterns represents different film layers. Different signal lines or functional units may be prepared in a same film layer. A plurality of light-shielding blocks 201 for blocking light may be provided in a same pixel driving circuit. When the light-shielding blocks 201 are used to block light and prevent the active area of the transistor from being irradiated by light and thus affecting the electrical characteristics of the transistor, even if the light-shielding blocks 201 are connected to each other, the light-shielding function of the light-shielding blocks 201 may not be affected.

In one embodiment, along the second direction, the light-shielding blocks 201 may be divided into a first group of light-shielding blocks 2011 and a second group of light-shielding blocks 2012. The first group of light-shielding blocks 2011 may be electrically connected to the first sub-power signal line, for example, the PVDD signal line. The second group of light-shielding blocks 2012 may be electrically connected to the second sub-power signal line, for example, the PVEE signal line. The signal lines connected to the first group of light-shielding blocks 2011 and the second group of light-shielding blocks 2012 respectively may be different.

After the first group of light-shielding blocks 2011 and the second group of light-shielding blocks 2012 are multiplexed to transmit PVDD signals and PVEE signals, the resistance of the first sub-power signal line and the second sub-power signal line may be reduced. Accordingly, the voltage drop of the first power signal corresponding to the first sub-power signal line and the second power signal corresponding to the second sub-power signal line received at different positions in the display panel may be reduced, and the uniformity of the display panel may be improved.

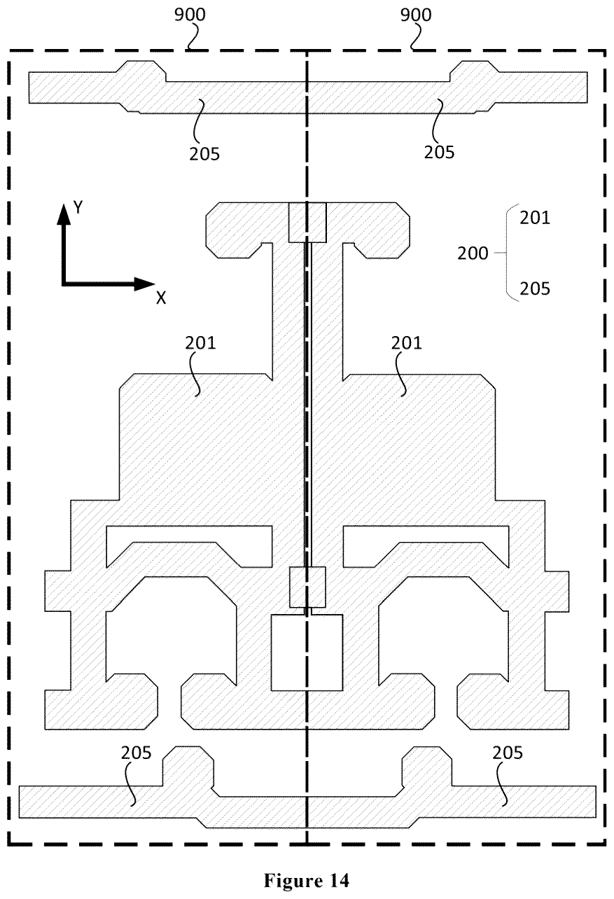

FIG. 14 illustrates a top view of another film layer stack structure of a display panel consistent with the disclosed embodiments of the present disclosure. In some embodiments, along the second direction, adjacent pixel drive circuits 900 are disposed in a mirrored way. In the two second signal lines 205 corresponding to the two adjacent pixel driving circuits 900 along the second direction, one of the second signal lines 205 is connected to the first sub-power signal line, and the other second signal line 205 is connected to the second sub-power signal line.

In FIG. 14, the X direction indicates the second direction. Each second signal line 205 may connect two adjacent pixel driving circuits 900 to form a line that may be used to transmit signals in the second direction. Taking the structure shown in FIG. 14 as an example, in one embodiment, two second signal lines 205 may be arranged sequentially along the Y direction. The second signal lines 205 may be connected to the second sub-power signal line and the first sub-power signal line in sequence. As a result, the resistance of the first sub-power signal line and the second sub-power signal line may be reduced. Accordingly, the voltage drop of the first power signal corresponding to the first sub-power signal line and the second power signal corresponding to the second sub-power signal line received at different positions in the display panel may be reduced, and the uniformity of the display panel may be improved.

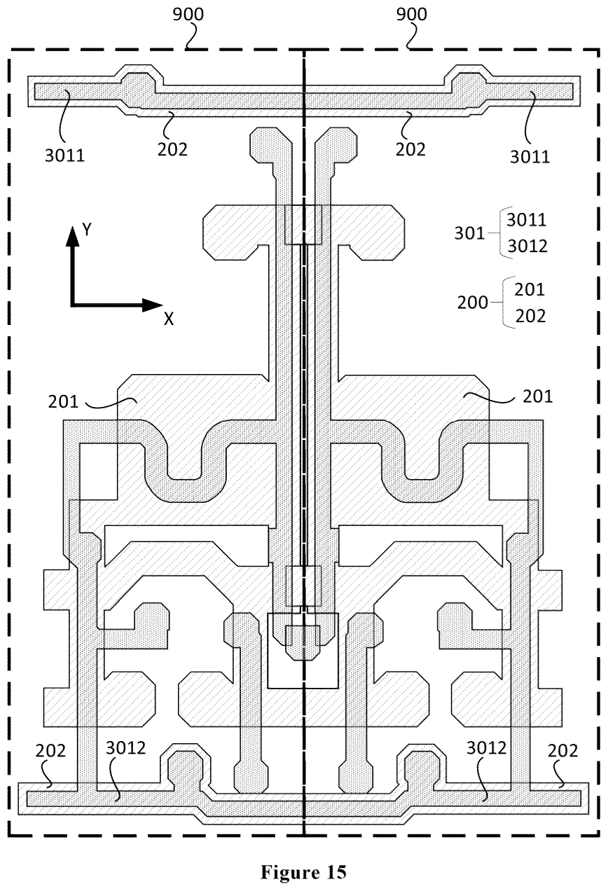

FIG. 15 illustrates a top view of another film layer stack structure of a display panel consistent with the disclosed embodiments of the present disclosure. In some embodiments, the reference power signal line 301 includes a first reference signal line 3011 and a second reference signal line 3012. In the two first signal lines 202 corresponding to two pixel driving circuits 900 adjacent in the first direction or the second direction, one of the first signal lines 202 is connected to the first reference signal line 3011, and the other first signal line 202 is connected to the second reference signal line 3012. The first direction intersects with the second direction.

In one embodiment, the first reference signal line 3011 may correspond to Vref1 in FIG. 8 and is electrically connected to the first reset transistor T5. The second reference signal line 3012 may correspond to Vref2 in FIG. 8 and is electrically connected to the second reset transistor T7.

In FIG. 15, the X direction represents the first direction, and the Y direction represents the second direction. The two first signal lines 202 in two adjacent pixel driving circuits 900 may be respectively connected to the first reference signal line 3011 and the second reference signal line 3012 to transmit the Vref1 signal and the Vref2 signal respectively. Accordingly, the voltage drop of the Vref1 signal received at different locations in the display panel may be reduced, and the voltage drop of the Vref2 signal received at different locations in the display panel may be reduced. The display uniformity of the display panel may thus be improved.

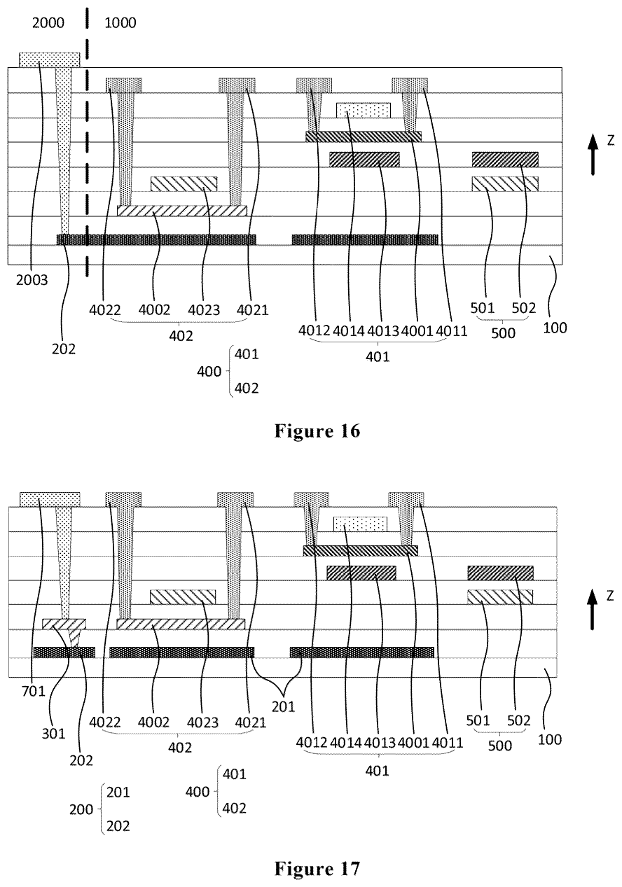

FIG. 16 illustrates another schematic film-structure diagram of a display panel consistent with the disclosed embodiments of the present disclosure. In some embodiments, the display panel also includes a display area 1000 and a non-display area 2000 at least partially surrounding the display area. The non-display area 2000 also includes a reference power main line 2003. The first signal line 202 extends from the display area 1000 to the non-display area 2000 and is connected to the reference power main line 2003.

The reference power main line 2003 represents a signal line for transmitting a reference power signal. In one embodiment, the reference power main line 2003 may be disposed in the non-display area. The first signal line 202 may be extended from the display area 1000 to the non-display area 2000 and connected to the reference power main line 2003 through a via. As such, space in the display area 1000 may be released.

Still referring to FIG. 3, in some embodiments, the first signal line 202 and the reference power signal line 301 may be electrically connected through a via in the overlapping area.

The first signal line 202 and the reference power signal line 301 may be electrically connected at any location. In one embodiment, the display area of the display panel has sufficient space, and the first signal line 202 and the reference power signal line 301 are connected through a via in the display area. As such, the resistance of the reference power signal line 301 may be reduced through the first signal line 202. Accordingly, the voltage drop of the reference power signal received by the transistors 400 at different positions in the display panel may be reduced, and the uniformity of the display panel may be improved.

FIG. 17 illustrates another schematic film-structure diagram of a display panel consistent with the disclosed embodiments of the present disclosure. In some embodiments, the display panel also includes a second conductive line layer located on a side of the reference power signal line 301 facing away from the base substrate 100. The second conductive line layer includes a reference auxiliary line 701. The reference auxiliary line 701 is electrically connected to the reference power signal line 301.

In one embodiment, the second conductive line layer is exemplarily disposed on a same layer as the source and drain metal layer. In addition to forming the source and drain metal layer, the second conductive line layer may also be used to form the reference auxiliary line 701. The reference auxiliary line 701 may be electrically connected to the reference power signal line 301 to transmit the reference power signal. As such, the resistance of the reference power signal line 301 may be reduced. Accordingly, the voltage drop of the power reference signal between the transistors 400 received at different positions in the display panel may be reduced, and the uniformity of the display panel may be improved. Since a large quantity of wirings are disposed in the display area, the quantity of wirings in the non-display area may be reduced. As a result, the space in the non-display area may be released, and the area of the non-display area may be reduced.

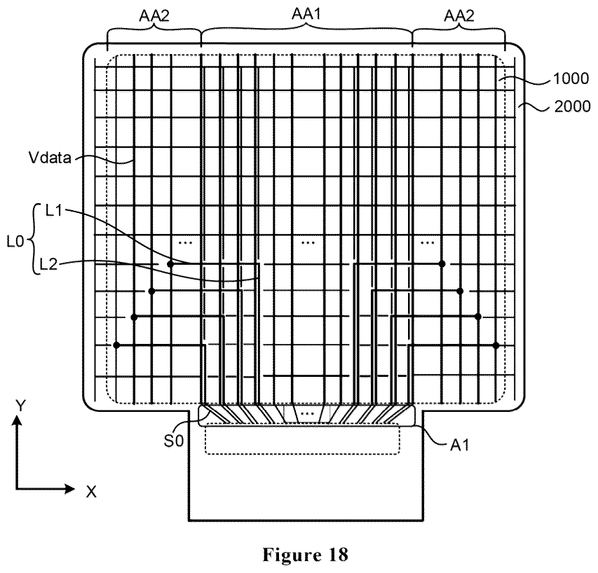

FIG. 18 illustrates a structural top view of another display panel consistent with the disclosed embodiments of the present disclosure. Referring to FIG. 18, in some embodiments, the display panel also includes a display area 1000 and a non-display area 2000 at least partially surrounding the display area 1000. The non-display area 2000 includes a fan-out area A1 located on one side of the display area 1000 along the first direction. The display area 1000 includes a first display area AA1 and a second display area AA2. The second display area AA2 is located on at least one side of the first display area AA1 along the second direction. The second direction intersects with the first direction. The fan-out area A1 includes a plurality of fan-out traces SO. The first display area AA1 and the second display area AA2 each include a plurality of data lines Vdata extending along the second direction and arranged along the first direction. The data lines Vdata are connected to the fan-out traces SO. The data lines Vdata of the second display area AA2 are connected to the fan-out traces SO through a connection trace L0. The connection trace L0 is located in the display area and includes a first connection segment L1 extending along the first direction and a second connection segment L2 extending along the second direction. The second connection segment L2 is electrically connected to the fan-out trace SO, and the first connection segment L1 is electrically connected to the data line Vdata in the second display area AA2. The second conductive line layer includes at least part of the connection traces L0.

Taking the orientation shown in FIG. 18 as an example, the fan-out area A1 is located on the lower side of the display area 1000, and the second display area AA2 is located on the left side and the right side of the first display area AA1. In some other embodiments, the second display area AA2 may also be located on the left side or the right side of the first display area AA1. The present disclosure does not limit a specific orientation relationship among the fan-out area A1, the first display area AA1, and the second display area AA2.

The display area 1000 is configured to display an image. The display area 1000 may include sub-pixels arranged in an array. The sub-pixel includes a pixel driving circuit 900 and a light-emitting element to achieve active light-emitting control and thereby achieve image display. The non-display area 2000 at least partially surrounds the display area 1000. For example, the non-display area 2000 may be set in at least part of the space on at least one side of the display area 1000. The non-display area 2000 may be used for laying out peripheral circuits and wiring to transmit display signals, such as driving signals and power signals, to the display area 1000. The non-display area 2000 is not used for displaying images, and may also be called a border area. A display panel with a low proportion of the non-display area 2000 in a plane area of the display panel may have a high proportion of the display area 1000 in the plane area. With increase of the proportion of the display area 1000, narrow-frame full-screen display may be achieved.

The fan-out area A1 includes a plurality of fan-out traces SO. The first display area AA1 and the second display area AA2 each include a plurality of data lines Vdata extending along the second direction Y and arranged along the first direction X. The data lines Vdata are connected to the fan-out traces SO. The data lines Vdata of the second display area AA2 are connected to the fan-out traces SO through the connection trace L0. The connection trace L0 is disposed in the display area 1000 and includes the first connection segment L1 extending along the first direction X and the second connection segment L2 extending along the second direction Y. The first connection segment L1 is electrically connected to the data line Vdata in the second display area AA2, and the second connection segment L2 is electrically connected to the fan-out line SO.

Taking the structure shown in FIG. 18 as an example, the first display area AA1 may be located in the middle area of the display panel, and the second display area AA2 may be located on two sides of the first display area AA1. As a result, the display panel may be designed to be left-right symmetric, and difficulty of laying out signal lines may be reduced.

The data line Vdata in the first display area AA1 may be directly electrically connected to the fan-out trace SO disposed in the fan-out area A1. The data line Vdata in the second display area AA2 may be electrically connected to the fan-out trace SO through the connection line L0 including the first connection segment L1 extending along the first direction X and the second connection segment L2 extending along the second direction Y. In this way, there is no need to lay fan-out traces close to the lower left frame and/or lower right frame of the display panel. Accordingly, a compressed space may be provided for the frame of the display panel and the display device, a narrow frame design of the display panel and the display device may be realized, and a display panel and a display device with a full screen may be achieved.

In one embodiment, the second conductive line layer 700 may include at least part of the connection traces L0 to ease the space of the non-display area 2000, and the area of the non-display area 2000 may be reduced.

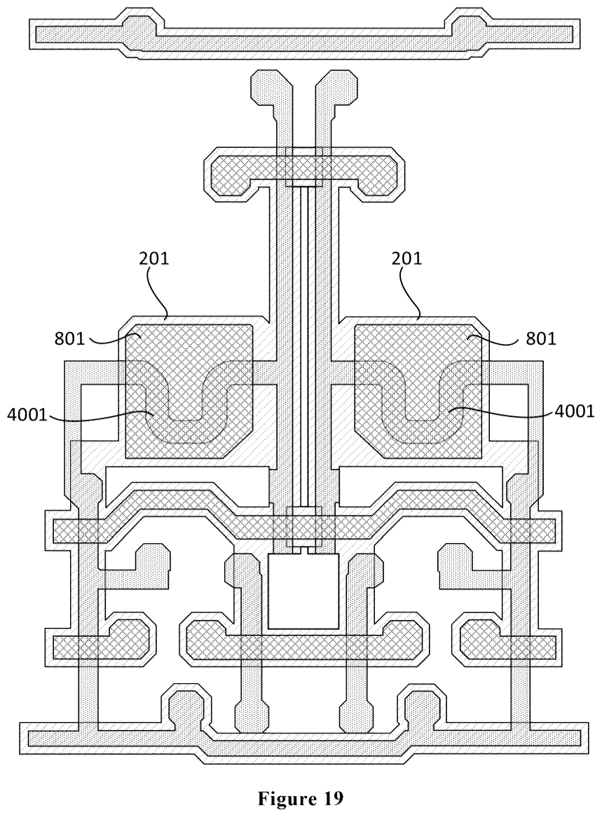

FIG. 19 illustrates a top view of another film layer stack structure of a display panel consistent with the disclosed embodiments of the present disclosure. In some embodiments, the display panel also includes a third conductive line layer located between the first semiconductor layer and the second semiconductor layer. The third conductive line layer includes a gate region 801. In the direction perpendicular to the plane of the base substrate 100, the gate region 801 is within the projection of the light-shielding block 201.

The third conductive line layer may be used to fabricate the gate region 801 of a transistor. The gate region 801 is configured to receive the control signal, to control the on/off state of the first transistor 401 and the second transistor 402. The gate area 801 is located within the projection of the light-shielding block 201. As such, the light-shielding block 201 may shield the gate region and the active area 4001 corresponding to the gate region, to prevent light from affecting the electrical characteristics of the transistor 400.

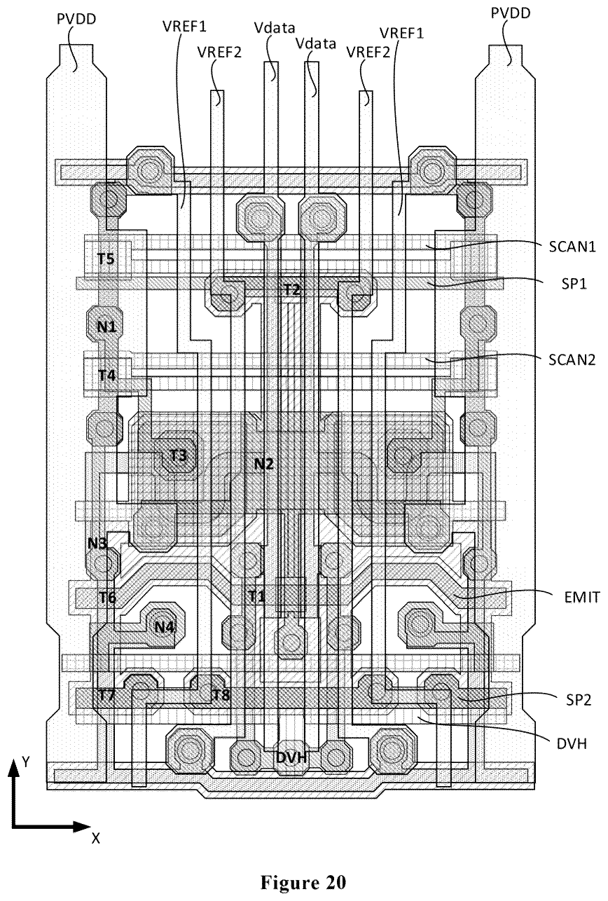

FIG. 20 illustrates a top view of another film layer stack structure of a display panel consistent with the disclosed embodiments of the present disclosure. FIG. 20 is a top view of a film layer stack structure corresponding to the pixel driving circuit 900 illustrated in FIG. 8. The plane formed by X and Y in FIG. 20 is the plane where the display panel is located. In one embodiment, in a display panel, the active area 4001 may be blocked by the light-shielding block 201 such that light may not irradiate the active area 4001. As such, the electrical characteristics of the active area 4001 may not be affected by light irradiation, and control signals may accurately control the on/off state of the transistor 400. Accordingly, the display performance and the display effect of the display panel may be improved, especially the display effect of the display panel in a lighting environment may be improved.

In one embodiment, a grid-like plane may be formed in the display panel through the first signal line 202, and then the reference power signal may be transmitted to the transistor 400 from a plurality of paths. As such, the transmission path of the reference power signal may be broadened, and the transmission efficiency of the reference power signal may be increased. Accordingly, the voltage drop of the reference power signal received by the transistors 400 at different positions of the display panel may be reduced, and the uniformity of the display panel may be improved.

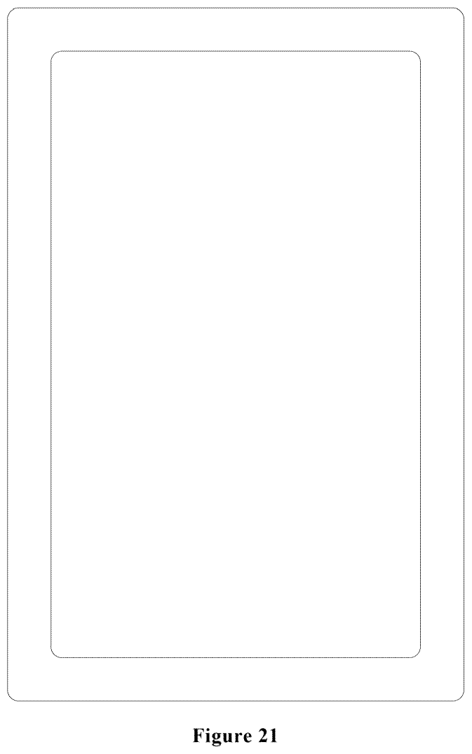

FIG. 21 illustrates a schematic structural diagram of a display device consistent with the disclosed embodiments of the present disclosure. The display device may include any of the display panels provided by the present disclosure, and may achieve same technical effects of the display panels provided by the present disclosure, which will not be elaborated here.

The display device includes but is not limited to a mobile phone, a tablet computer, a vehicle-mounted computer, a smart wearable device with a display function, and other structural components with a display function, which will not be elaborated or limited here.

As disclosed, the technical solutions of the present disclosure have the following advantages.

In the display panel and display device provided by the present disclosure, a light-shielding layer including a light-shielding block and a first signal line is provided. In a direction perpendicular to a plane of a base substrate, an active area of at least one transistor overlaps with the light-shielding block. As such, the light-shielding block may be used to block the active area of the transistor overlapping with the light-shielding block, such that external light may not irradiate the active area of the transistor. As such, the impact of external light on the electrical characteristics of the transistor, such as leakage current, may be weakened, and the on/off control accuracy of the transistor may be improved. Accordingly, the display effect of the display panel in lighting environment may be improved.

In addition, the first signal line and the reference power signal line are electrically connected and extend in a same direction. In a direction perpendicular to a plane of the base substrate, the first signal line and the reference power signal line overlap. As such, the first signal line may be used to reduce the resistance of the reference power signal line. Accordingly, voltage drop difference of the reference power signal in the reference power signal line at different positions in the display panel may be reduced, consistency of the reference power signal at different positions of the display panel may be improved, and display uniformity of the display panel may thus be improved. Moreover, since the first signal line occupies a small additional area in the plane of the base substrate, space may be reserved for laying out other wirings and other structures, and the flexibility of laying out other wirings and other structures may be improved.

It should be noted that in the present disclosure, relational terms such as “first” and “second” are only used to distinguish one entity or operation from another entity or operation, and do not necessarily require or imply that such actual relationship or sequence exists between these entities or operations. Terms “comprise”, “include” or any other variations thereof are intended to cover a non-exclusive inclusion. A process, method, article, or apparatus that includes a series of elements includes not only the series of elements, but also other elements not expressly listed, or elements inherent to such process, method, article, or apparatus. Without further limitation, an element defined by a statement like “comprises a . . . ” does not exclude the presence of additional identical elements in a process, method, article, or apparatus that includes the foregoing element.

The embodiments disclosed herein are exemplary only and not limiting the scope of the present disclosure. Various combinations, alternations, modifications, equivalents, or improvements to the technical solutions of the disclosed embodiments may be obvious to those skilled in the art. Without departing from the spirit and scope of this disclosure, such combinations, alternations, modifications, equivalents, or improvements to the disclosed embodiments are encompassed within the scope of the present disclosure.

What is claimed is:

1. A display panel, comprising:
a pixel driving circuit, including a plurality of transistors;
a base substrate;
a light-shielding layer, disposed on a side of the base substrate, wherein the light-shielding layer includes a light-shielding block and a first signal line, and in a direction perpendicular to a plane of the base substrate, an active area of at least one transistor of the plurality of transistors overlaps with the light-shielding block; and
a reference power signal line, wherein the first signal line and the reference power signal line are electrically connected, extension directions of the first signal line and the reference power signal line are consistent, and in the direction perpendicular to the plane of the base substrate, the first signal line overlaps with the reference power signal line.

2. The display panel according to claim 1, wherein:
the plurality of transistors includes a first transistor and a second transistor; and
the pixel driving circuit further includes a first capacitor, a first semiconductor layer, and a second semiconductor,
wherein:
the first transistor and the second transistor each are electrically connected to the first capacitor;
the first semiconductor layer is disposed on a side of the light-shielding layer facing away from the base substrate, and the first semiconductor layer includes an active area of the first transistor; and
the second semiconductor layer is disposed between the first semiconductor layer and the light-shielding layer, and the second semiconductor layer includes an active area of the second transistor.

3. The display panel according to claim 2, wherein:
the second semiconductor layer and the first semiconductor layer are made of different materials.

4. The display panel according to claim 1, further comprising a third semiconductor layer,
wherein:
the third semiconductor layer includes an active area of at least one transistor of the plurality of transistors; and
the reference power signal line and the third semiconductor layer are disposed on a same layer.

5. The display panel according to claim 1, wherein:
the plurality of transistors includes a power writing transistor, a data writing transistor, a driving transistor, a first reset transistor, a threshold compensation transistor, a light-emitting control transistor, and a second reset transistor; and
the pixel driving circuit further includes a second capacitor,
wherein:
the threshold compensation transistor is electrically connected between a gate and a first electrode of the driving transistor;
a first electrode of the power writing transistor and a first electrode of the data writing transistor each are electrically connected to a second electrode of the driving transistor, and a second electrode of the power writing transistor is electrically connected to a second plate of the second capacitor;
a gate of the driving transistor and a first electrode of the first reset transistor each are electrically connected to a first plate of the second capacitor;
at least one of a second electrode of the first reset transistor and a second electrode of the second reset transistor is electrically connected to the reference power signal line;
the light-emitting control transistor is connected between the driving transistor and a light-emitting element driven by the pixel driving circuit; and
a first electrode of the second reset transistor is electrically connected to the light-emitting control transistor and the light-emitting element.

6. The display panel according to claim 5, wherein:
the plurality of transistors further includes a bias transistor, wherein the bias transistor is electrically connected to the second electrode of the driving transistor.

7. The display panel according to claim 1, further comprising a display area and a non-display area at least partially surrounding the display area, wherein:
the light-shielding layer further includes an extension portion, wherein in the display area, the extension portion is connected to the light-shielding block, and extends to the non-display area; and
the non-display area includes a first power main line, and the extension portion is electrically connected to the first power main line.

8. The display panel according to claim 1, further comprising a first conductive line layer disposed on a side of the light-shielding layer facing away from the base substrate,
wherein:
the first conductive line layer includes a first power signal line;
in the direction perpendicular to the plane of the base substrate, the first power signal line overlaps with a second signal line, and the first power signal line and the second signal line are electrically connected through a via in an overlapping area of the first power signal line and the second signal line; and
the second signal line includes the light-shielding blocks that are connected to each other.

9. The display panel according to claim 1, further comprising a first power signal line,
wherein:
the first power signal line extends at least along a second direction;
the light-shielding layer further includes a connecting portion, where at least the light-shielding blocks arranged along a first direction are connected to each other through the connecting portion, and are connected to the first power signal line; and
the first direction intersects with the second direction.

10. The display panel according to claim 9, wherein:
the first power signal line includes a first sub-power signal line and a second sub-power signal line;
at least the light-shielding blocks arranged along the first direction are connected to each other through the connecting portion to form at least two second signal lines extending along the first direction, and the first direction intersects with the second direction; and
at least one second signal line of the at least two second signal lines is electrically connected to the first sub-power signal line, and at least another second signal line of the at least two second signal lines is electrically connected to the second sub-power signal line.

11. The display panel according to claim 10, wherein:
the first signal line extends along the first direction;
along the second direction, the light-shielding blocks that overlap with a same pixel driving circuit of the pixel driving circuit in the direction perpendicular to the plane of the base substrate are divided into a first group of light-shielding blocks and a second group of light-shielding blocks;
along the first direction, at least part of the first group of light-shielding blocks in the display panel are connected to each other, and are connected to one of the first sub-power signal line and the second sub-power signal line; and
along the first direction, at least part of the second group of light-shielding blocks in the display panel are connected to each other, and are connected to another one of the first sub-power signal line and the second sub-power signal line.

12. The display panel according to claim 10, wherein:
along the second direction, adjacent pixel drive circuits of the pixel drive circuits are disposed in a mirrored way; and
in two second signal lines of the at least two second signal lines, corresponding to two pixel driving circuits adjacent along the second direction, of the pixel drive circuits, one of the two second signal lines is connected to the first sub-power signal line, and another one of the two second signal lines is connected to the second sub-power signal line.

13. The display panel according to claim 1, wherein:
the reference power signal line includes a first reference signal line and a second reference signal line;
in two first signal lines of the first signal lines, corresponding to two of the pixel driving circuits adjacent in the first direction or the second direction, one of the two first signal lines is connected to the first reference signal line, and another one of two first signal lines is connected to the second reference signal line; and
the first direction intersects with the second direction.

14. The display panel according to claim 1, further comprising a display area and a non-display area at least partially surrounding the display area, wherein:
the non-display area further includes a reference power main line; and
the first signal line extends from the display area to the non-display area, and is connected to the reference power main line.

15. The display panel according to claim 1, wherein:
the first signal line and the reference power signal line are electrically connected through a via in an overlapping area of the first signal line and the reference power signal line.

16. The display panel according to claim 1, further comprising a second conductive line layer located on a side of the reference power signal line facing away from the base substrate,
wherein:
the second conductive line layer includes a reference auxiliary line; and
the reference auxiliary line is electrically connected to the reference power signal line.

17. The display panel according to claim 16, further comprising a display area and a non-display area at least partially surrounding the display area, wherein:
the non-display area includes a fan-out area located on one side of the display area along a first direction;
the display area includes a first display area and a second display area, the second display area is located on at least one side of the first display area along a second direction, and the second direction intersects with the first direction; and
the fan-out area includes a plurality of fan-out traces, the first display area and the second display area each include a plurality of data lines extending along the second direction and arranged along the first direction, and the plurality of data lines is connected to the plurality of fan-out traces.

18. The display panel according to claim 17, wherein:
a data line of the plurality of data lines of the second display area is connected to a fan-out trace of the plurality of fan-out traces through a connection trace;
the connection trace is located in the display area and includes a first connection segment extending along the first direction and a second connection segment extending along the second direction;
the second connection segment is electrically connected to the fan-out trace, and the first connection segment is electrically connected to the data line of the second display area; and
the second conductive line layer includes at least part of the connection traces.

19. The display panel according to claim 2, further comprising a third conductive line layer,
wherein:
the third conductive line layer is disposed between the first semiconductor layer and the second semiconductor layer, and includes a gate region; and
in the direction perpendicular to the plane of the base substrate, the gate region is within a projection of the light-shielding block.

20. A display device, comprising a display panel including:
a pixel driving circuit, including a plurality of transistors;
a base substrate;
a light-shielding layer, disposed on a side of the base substrate, wherein the light-shielding layer includes a light-shielding block and a first signal line, and in a direction perpendicular to a plane of the base substrate, an active area of at least one transistor of the plurality of transistors overlaps with the light-shielding block; and
a reference power signal line, wherein the first signal line and the reference power signal line are electrically connected, extension directions of the first signal line and the reference power signal line are consistent, and in the direction perpendicular to the plane of the base substrate, the first signal line overlaps with the reference power signal line.
